(19) United States
(12) Patent Application Publication
(10) Pub. No.: US 2006/0232308 A9
(43) Pub. Date: Oct. 19, 2006

(54) Delay stabilization circuit and semiconductor integrated circuit

(76) Inventor: Ichiro Kumata, Kanagawa (JP)

Correspondence Address: William E. Vaughan;Bell, Boyd & Lloyd LLC, P.O. Box 1135, Chicago, IL, 60690, US

(21) Appl. No.: 11/292,637

(22) Filed: Dec. 1, 2005

(30) Foreign Application Priority Data
Dec. 2, 2004 (JP) P2004-350377

(51) Int. Cl. H03L 7/06

(52) U.S. Cl. 327/158; 327/270

(57) ABSTRACT

A delay stabilization circuit capable of suppressing a drop in stability of delay or frequency and a cost increase and also able to shorten a design time, and a semiconductor integrated circuit are provided. The delay stabilization circuit includes a passive noise filter configured by a capacitor and a resistor, a variable delay circuit including a logic gate to which power of a power source is supplied through the noise filter, and a feedback control circuit for suppressing delay fluctuation of the variable delay circuit using a clock input from the outside as a reference.

### CROSS REFERENCE TO RELATED APPLICATION

The present application claims priority to Japanese Patent Application No. 2004-350377 filed in the Japan Patent Office on Dec. 2, 2004, the entire contents of which is being incorporated herein by reference.

### BACKGROUND

The present invention relates to a phase locked loop (PLL), delay locked loop (DDL), or other delay stabilization circuit having a delay feedback control mechanism and a semiconductor integrated circuit.

When the output of a delay stabilization circuit is inverted and returned to the input for constant oscillation, a PLL is formed. Further, a delay stabilization circuit is used in an open loop by a DLL used in a double data rate (DDR) dynamic random access memory (DRAM) and other circuits.

In a PLL, DLL, or other delay stabilization circuit having a delay feedback control mechanism, if there is any power supply noise having a frequency component of a cycle sufficiently longer than the feedback cycle, most of its effects are absorbed by the delay feedback control.

However, if an abrupt fluctuation of the power supply or noise having a frequency component shorter than the delay feedback cycle occurs, the delay ends up fluctuating due to its effect.

In order to reduce the effect of such fluctuation of the power supply, in an analog system, sometimes a power supply voltage stabilization circuit is added on the chip or an effect suppression function of the voltage fluctuation is built into a variable delay circuit. However, an analog system tends to become larger in circuit size in comparison with a digital system and also takes a longer time for design.

On the other hand, in a digital system configured by only logic gates, new generations of processing technology have made it easy to reduce the circuit scale and power consumption and have facilitated design. However, the delay of logic gates fluctuates due to fluctuations in the power supply voltage, therefore it is difficult to suppress the effect of the high frequency component of noise, unable to be tracked by feedback control, by modification of the delay circuit per se.

Therefore, when a high delay precision is required in a digital system, either a voltage stabilization circuit using transistors provided on the chip is used or a dedicated stabilization power supply is provided on the outside, but the cost becomes that much higher.

Regarding utilization of a power supply filter configured by only passive elements, a filter configured by a resistor and a capacitor is not used since common sense dictates that there will be a voltage drop due to the resistance. Further, a filter configured by an inductor or a combination of an inductor and a capacitor, such as used for a general power supplies, has a resonance frequency. When the voltage sharply changes such as when turning on the power and turning it off and when there is noise having many components near the resonance frequency, the voltage fluctuation is large. For this reason, use has been difficult. Further, mounting an inductor on a large scale integrated circuit (LSI) is difficult.

### SUMMARY

It is therefore desirable to provide a delay stabilization circuit able to suppress a drop in the stability of delay or frequency and a cost increase and able to shorten the design time and a semiconductor integrated circuit.

According to a first aspect of an embodiment of the present invention, there is provided a delay stabilization circuit comprising a passive noise filter configured by a capacitor and a resistor, a variable delay circuit including a logic gate to which power of a power source is supplied through the noise filter, and a feedback control circuit for suppressing delay fluctuation of the variable delay circuit using a clock input from the outside as a reference.

Preferably, the delay stabilization circuit has a pin for connecting only the capacitor forming the noise filter, the resistor forming the noise filter is mounted on an integrated circuit the same as the variable delay circuit, the capacitor forming the noise filter is arranged on the outside of the chip, and the capacitor forming the noise filter is connected to the pin.

Alternatively, the resistor and the capacitor forming the noise filter are mounted on the integrated circuit with the variable delay circuit.

Alternatively, at least the variable delay circuit is separated in power supply from the other circuits mounted on the same integrated circuit, and power from the power source is supplied by the noise filter.

Alternatively, a time constant of the noise filter is set sufficiently larger than the cycle of the delay feedback control.

According to a second aspect of an embodiment of the present invention, there is provided a delay stabilization circuit comprising a passive noise filter configured by a capacitor and a resistor, a ring oscillator including a variable delay circuit including a logic gate to which a power of a power source is supplied through the noise filter, and a feedback control circuit outputting a delay control signal for suppressing delay fluctuation of the variable delay circuit using a clock input from the outside as a reference to the variable delay circuit, wherein the clock is output by the ring oscillator.

According to a third aspect of an embodiment of the present invention, there is provided a delay stabilization circuit comprising a passive noise filter configured by a capacitor and a resistor, a ring oscillator including a variable delay circuit including a logic gate to which a power of a power source is supplied through the noise filter, at least one output use delay variable circuit supplied with power of the power source through the noise filter and delaying the input signal with a delay amount in accordance with the delay control signal; and a feedback control circuit outputting a delay control signal for suppressing delay fluctuation of the variable delay circuit using a clock input from the outside as a reference to the variable delay circuit of the ring oscillator and the output use variable delay circuit.

According to a fourth aspect of an embodiment of present invention, there is provided a semiconductor integrated circuit comprising a passive noise filter configured by a capacitor and a resistor, a ring oscillator including a variable delay circuit having a logic gate and outputting a clock, a feedback control circuit outputting a delay control signal for suppressing delay fluctuation of the variable delay circuit using a clock input from the outside as a reference to the variable delay circuit, and a logic circuit using an output clock of the ring oscillator as an operation clock, wherein at least the ring oscillator, feedback control circuit, and logic circuit are mounted on the same integrated circuit, power from a power source is supplied to at least the logic circuit, and power of the power source passed through the noise filter is supplied to at least the variable delay circuit of the ring oscillator.

According to a fifth aspect of an embodiment of the present invention, there is provided a semiconductor integrated circuit comprising a passive noise filter configured by a capacitor and a resistor, a ring oscillator including a variable delay circuit having a logic gate, at least one output use delay variable circuit supplied with power of a power source through the noise filter and delaying an input signal with a delay amount in accordance with a delay control signal, a feedback control circuit outputting a delay control signal for suppressing delay fluctuation of the variable delay circuit using a clock input from the outside as a reference to the variable delay circuit of the ring oscillator and the output use variable delay circuit, and a logic circuit for receiving the output signal of the output use variable delay circuit and performing predetermined processing, wherein at least the output use variable delay circuit, ring oscillator, feedback control circuit, and logic circuit are mounted on the same integrated circuit, power from the power source is supplied to at least the logic circuit, and power of the power source passed through the noise filter is supplied to at least the output use variable delay circuit and the variable delay circuit of the ring oscillator among the output use variable delay circuit, the variable delay circuit, and feedback control circuit.

According to embodiments of the present invention, the noise filter functions as a passive power supply filter configured by a capacitor and a resistor (CR passive filter) and supplies power supply voltage from the original power source to the delay stabilization circuit as a whole or supplies the power passed through the passive power supply filter configured by the resistor and the capacitor to a portion including the variable delay circuit as drive power.

According to embodiments of the present invention, a drop in stability of delay or frequency and a cost increase can be suppressed, and also the design time can be shortened.

Additional features and advantages are described herein, and will be apparent from, the following Detailed Description and the figures.

### BRIEF DESCRIPTION OF THE DRAWINGS

FIG. 1 is a circuit diagram of a delay stabilization 10 circuit according to a first embodiment of the present invention.

FIG. 2 is a circuit diagram of a first example of the configuration of a digital variable delay circuit according to the first embodiment of the present invention.

FIG. 3 is a circuit diagram of a second example of the configuration of a digital variable delay circuit according to the first embodiment of the present invention.

FIG. 4 is a block diagram of an example of the configuration of a delay feedback control circuit according to the first embodiment of the present invention.

FIG. 5 is a circuit diagram of a first example of the configuration of a noise filter (CR passive filter) according to the first embodiment of the present invention.

FIG. 6 is a circuit diagram of a second example of the configuration of a noise filter (CR passive filter) according to the first embodiment of the present invention.

FIG. 7 is a diagram of a situation of power supply noise and delay fluctuation of a variable delay circuit where a noise filter (power supply filter) is provided as in the present embodiment.

FIG. 8 is a diagram of the situation of power supply noise and delay fluctuation of a variable delay circuit where a noise filter (power supply filter) is not provided.

FIG. 9 is a circuit diagram of a delay stabilization circuit according to a second embodiment of the present invention.

FIG. 10 is a circuit diagram of a delay stabilization circuit integrated in a semiconductor according to a third embodiment of the present invention.

FIG. 11 is a circuit diagram of a delay stabilization circuit integrated in a semiconductor according to a fourth embodiment of the present invention.

FIG. 12 is a circuit diagram of a delay stabilization circuit integrated in a semiconductor according to a fifth embodiment of the present invention.

FIG. 13 is a circuit diagram of a delay stabilization circuit integrated in a semiconductor according to a sixth embodiment of the present invention.

FIG. 14 is a diagram for explaining a DDR interface.

FIGS. 15A-15D illustrate a timing chart for explaining an operation of a DLL functioning as a DDR interface.

FIG. 16 is a circuit diagram of a delay stabilization circuit integrated in a semiconductor according to a seventh embodiment of the present invention.

### DETAILED DESCRIPTION

0039 Below, various embodiments of the present invention will be explained in greater detail without limitation and with reference to the attached drawings.

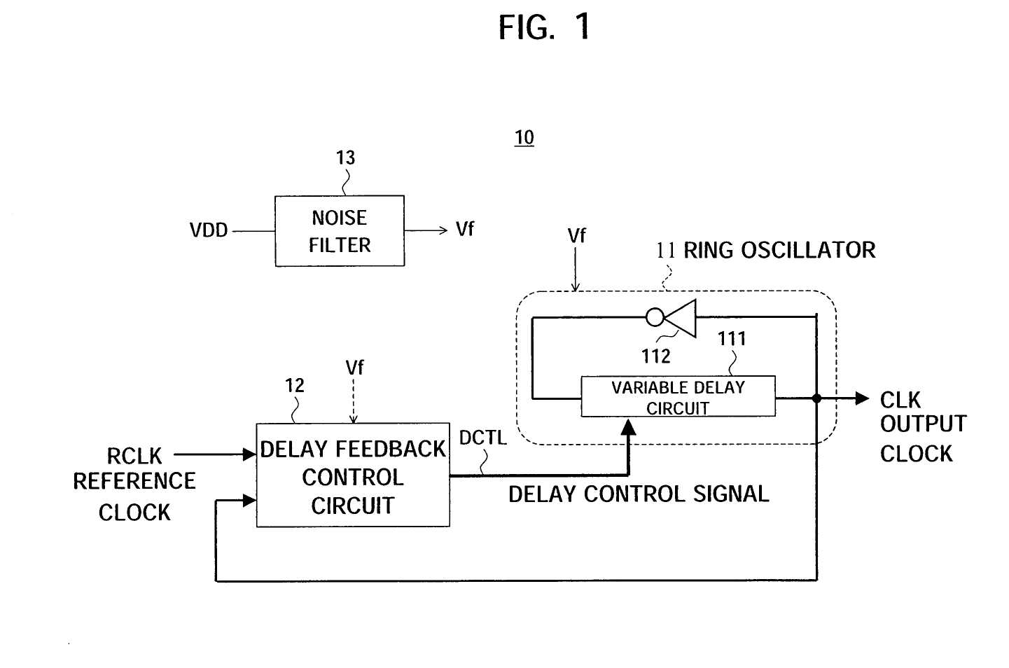

FIG. 1 is a circuit diagram of a delay stabilization circuit according to a first embodiment of the present invention. The delay stabilization circuit of the first embodiment is an example of the configuration in a case of a PLL.

A delay stabilization circuit 10 of the first embodiment, as shown in FIG. 1, has a ring oscillator 11, a delay feedback control circuit 12, and a noise filter (power supply filter) 13 as principal components. The present embodiment is, as will be explained later, comprised as a passive filter configured by a capacitor and a resistor and supplies a power supply voltage VDD from a not shown original power source as a voltage Vf to the ring oscillator 11 or both of the ring oscillator 11 and the delay feedback control circuit 12.

The ring oscillator 11 is comprised as a ring by a variable delay circuit 111 and an inverter 112 having an input terminal connected to the output of the variable delay circuit 111 and an output terminal connected to the input. The ring oscillator 11 is supplied with the power supply voltage Vf passed through the noise filter 13 as the drive power, delays an oscillation clock CLK with a delay amount in accordance with a delay control signal DCTL, and outputs the result.

This ring oscillator 11 functions as a delay measurement signal generation circuit. The delay measurement signal generation circuit outputs a delay measurement signal having a delay or an oscillation cycle proportional to the delay of the variable delay circuit. When the variable delay circuit is utilized as a ring oscillator as in a PLL, the variable delay circuit itself can also be used as the delay measurement signal generation circuit.

The variable delay circuit 111 is a digital variable delay circuit configured by a logic gate, is controlled so as to reduce the delay fluctuation by the delay control signal DCTL from the delay feedback control circuit 12, and outputs the clock CLK with a delay amount in accordance with the delay control signal DCTL.

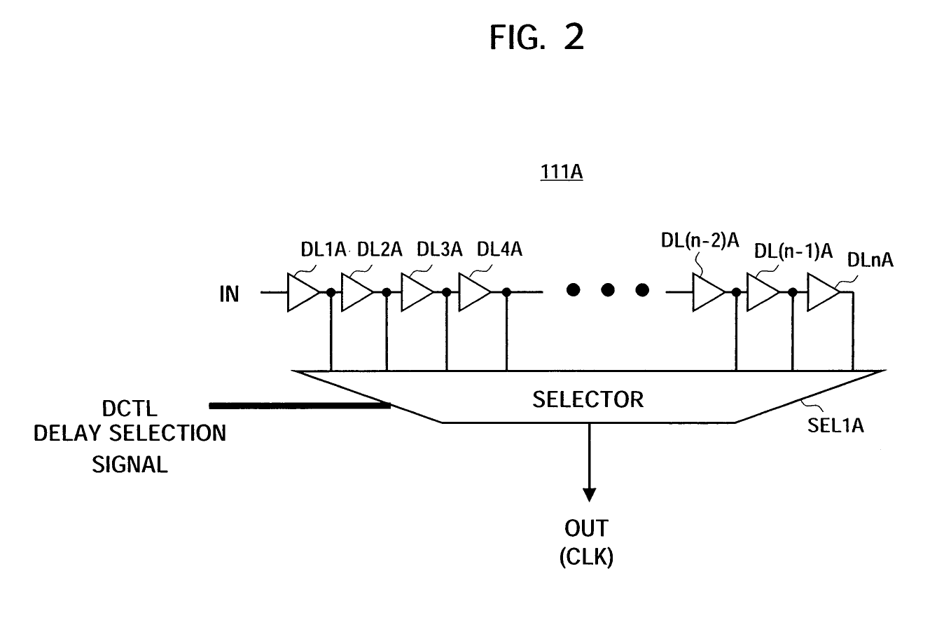

FIG. 2 is a circuit diagram of a first example of the configuration of a digital variable delay circuit according to the first embodiment of the present invention. A variable delay circuit 111A of FIG. 2 has a plurality of delay elements (buffers) DL1A to DLnA connected in series to a supply line of an input signal IN (output line of the inverter 112 in the configuration of FIG. 1) and a selector SEL1A for selecting and outputting one of the outputs of the delay elements DL1A to DLnA in accordance with the delay control signal DCTL.

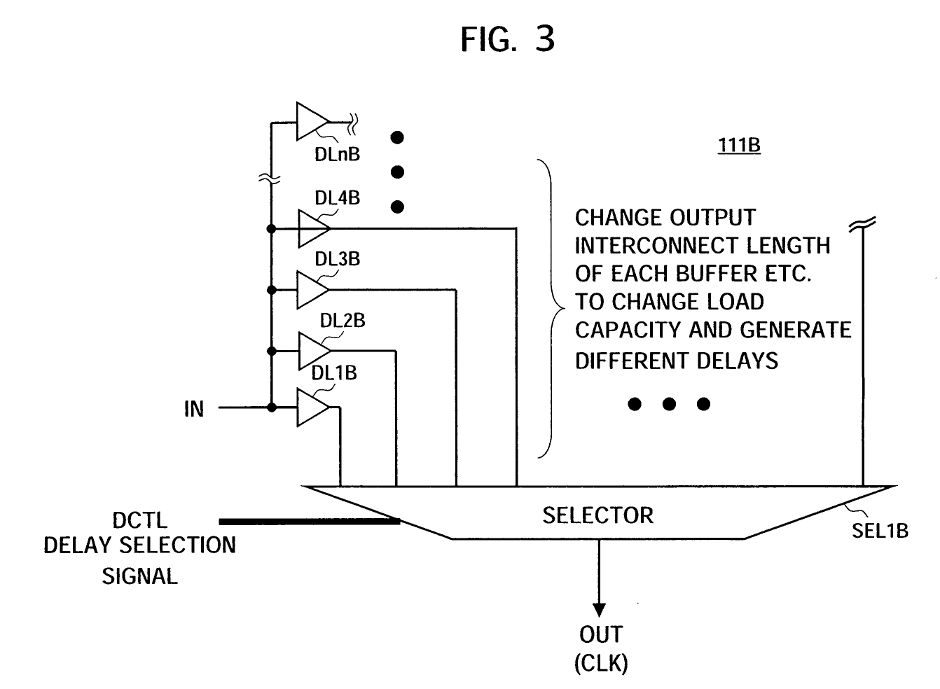

FIG. 3 is a circuit diagram of a second example of the configuration of a digital variable delay circuit according to the first embodiment of the present invention.

A variable delay circuit 111B of FIG. 3 has a plurality of delay elements (buffers) DL1B to DLnB connected in parallel to the supply line of the input signal IN (output line of the inverter 112 in the configuration of FIG. 1) and a selector SEL1B for selecting and outputting one of the outputs of the delay elements DL1B to DLnB in accordance with the delay control signal DCTL. The variable delay circuit 111B of FIG. 3 changes output interconnect lengths of the delay elements DL1B to DLnB etc. to change the load capacitance and generate different delays.

The ring oscillator 11 having the above configuration, as explained above, functions as a delay measurement signal generation circuit. This delay measurement signal generation circuit outputs a delay measurement signal CLK having a delay or oscillation cycle proportional to the delay of the variable delay circuit 111 to the outside and the delay feedback control circuit 12.

The delay feedback control circuit 12 compares a reference clock RCLK input from the outside and the output signal CLK of the ring oscillator 11 in phase and frequency, generates a delay control signal DCTL for suppressing the delay fluctuation of the variable delay circuit 111 of the ring oscillator 11, and outputs the same to the variable delay circuit 111.

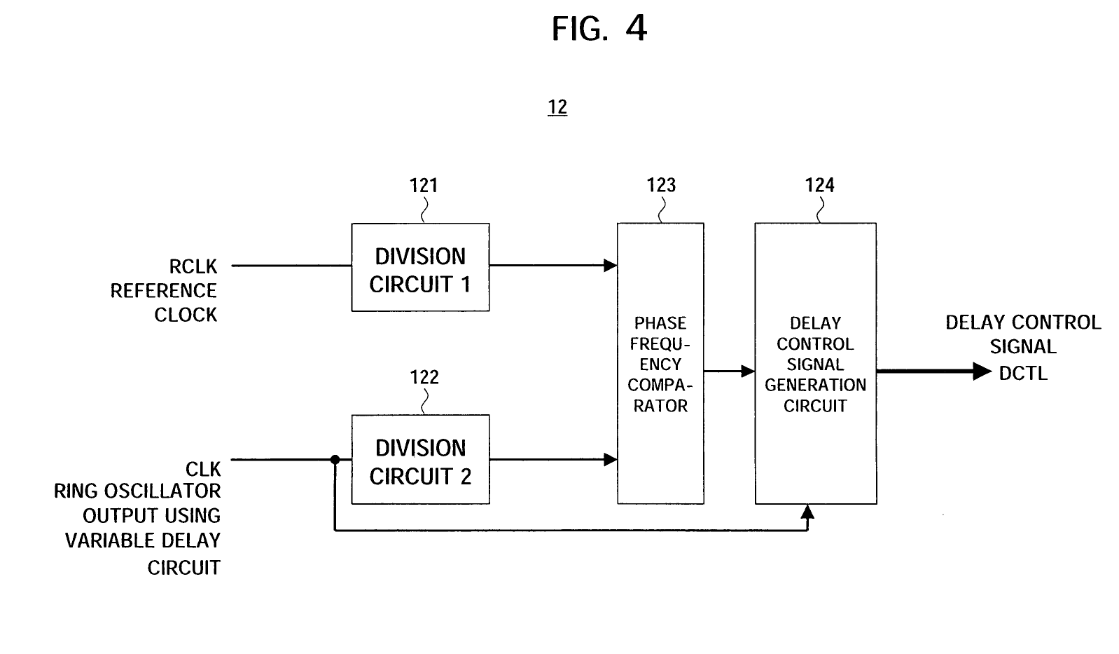

FIG. 4 is a block diagram of an example of the configuration of the delay feedback control circuit according to the first embodiment of the present invention.

The delay feedback control circuit 12 of FIG. 4 has frequency division circuits 121 and 122, a phase frequency comparator 123, and a delay control signal generation circuit 124. The frequency division circuit 121 divides the reference clock RCLK input from the outside by a predetermined frequency division ratio and outputs it to the phase frequency comparator 123. The frequency division circuit 122 divides the output clock CLK of the ring oscillator 11 by a predetermined frequency division ratio and outputs it to the phase frequency comparator 123. The phase frequency comparator 123 compares phases and frequencies of the reference clock and the output clock from the frequency division circuits 121 and 122 and outputs the result of comparison to the delay control signal generation circuit 124. The delay control signal generation circuit 124 receives the result of comparison of the phase frequency comparator 123 and the output clock CLK of the ring oscillator 11, generates the delay control signal DCTL for controlling the delay amount of the variable delay circuit 111, and outputs the same to the variable delay circuit 111.

The noise filter 13 functions as the passive power supply filter configured by the capacitor and the resistor (CR passive filter) and supplies the power supply voltage VDD from a not shown original power source to the delay stabilization circuit 10 as a whole or supplies the voltage Vf passed through the passive power supply filter configured by the resistor and the capacitor to a portion including the variable delay circuit ill (ring oscillator in the configuration of FIG. 1) as drive power.

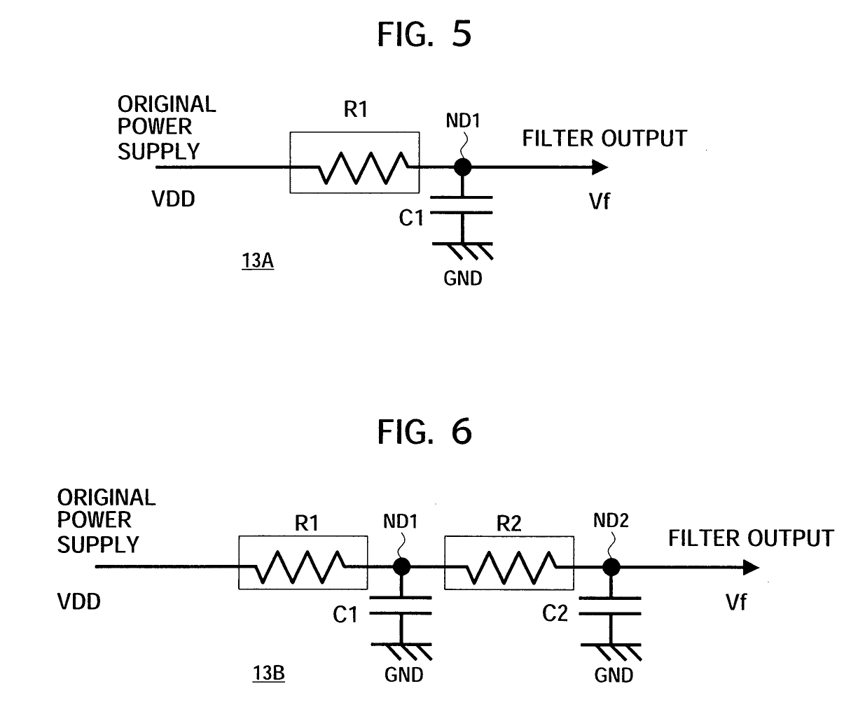

FIG. 5 is a circuit diagram of a first example of the configuration of the noise filter (CR passive filter) according to the first embodiment of the present invention.

The CR passive filter 13A of FIG. 5 is formed as a filter having a single-stage configuration including a resistor R1 and a capacitor C1. One end of the resistor R1 is connected to the supply line of the power supply voltage VDD, and the other end is connected to a first electrode of the capacitor C1. The voltage Vf after filtering is output from a connection node ND1 thereof. The second electrode of the capacitor C1 is grounded.

FIG. 6 is a circuit diagram of a second example of the configuration of the noise filter (CR passive filter) according to the first embodiment of the present invention.

A CR passive filter 13B of FIG. 5 is formed as a filter having a two-stage configuration including resistors R1 and R2 and capacitors C1 and C2. One end of the resistor R1 is connected to the supply line of the power supply voltage VDD of the original power source, the other end is connected to the first electrode of the capacitor C1, and the second electrode of the capacitor C1 is grounded. One end of the resistor R2 is connected to the connection node ND1 of the resistor R1 and the capacitor C1, the other end is connected to the second electrode of the capacitor C2, and the voltage Vf after filtering is output by the connection node ND2 thereof. The second electrode of the capacitor C2 is grounded.

As will be explained in detail later, in a case where a delay stabilization circuit configured as a PLL (or DLL) is mounted on the LSI and in a case where there is another logic circuit which becomes a large noise source on the LSI, the noise filter 11 having such configuration is arranged so as to separate in power supply the circuit which become the noise source and the variable delay circuit, the entire delay stabilization circuit, or the portion of the delay stabilization circuit where the effect on delay stability is large from the other logic circuit which becomes the noise source.

The value of the resistor R of the noise filter (power supply filter) is set to a value giving a small enough voltage drop so that the digital circuit operates without problem. The capacitance of the capacitor C is selected so as to give the required stability of the delay. More specifically, use is made of a value satisfying the following conditions.

When the voltage of the original power source is VDD, the output side voltage of the power supply filter is Vf, the lower limit power supply voltage of the digital circuit is Vmin, and a peak-to-peak value of the power supply noise from the outside is Vnoise, under condition 1. Vf≧Vmin condition 2. voltage fluctuation width=Vnoise width around VDD, a desired delay stability is obtained in the operation of the delay circuit when a square wave having a pulse length sufficiently longer than (for example 10 times) the feedback cycle of the delay stabilization circuit is input to the delay stabilization circuit through the power supply filter as the power supply voltage including noise.

By satisfying the above condition 2, even when power supply noise having a variety of waveforms is input, the desired delay stability is obtained by the CR power supply filter and feedback circuit.

Both of the above conditions 1 and 2 can be verified by simulation by SPICE or measurement of an actual circuit so as to determine the resistance value and the capacitance value.

When the condition of 1 cannot be satisfied, the resistance value of the filter may be made smaller. When the condition of 2 cannot be satisfied, the capacitance of the capacitor may be made larger or the resistance value may be made larger within a range satisfying the condition of 1, or the number of stages of the filter may be increased after satisfying the condition of 1.

The reason for use of a square wave as the noise under the condition 2 is that correction of the delay fluctuation by the feedback operation is not effective immediately after the rising or falling of the square wave when the time of rising or falling of the square wave is sufficiently shorter than the delay feedback cycle. Therefore, it considered that the delay fluctuation becomes the worst value.

When the delay stabilization circuit does not operate intermittently, but operates continuously, the resistance value matching with the condition of 1 can also be roughly calculated from the following relation where the power supply current flowing in the noise filter (power supply filter) is I and the total resistance value of the power supply filter is R:
VDD Vmin>VDD Vf=I·R

Below, the power supply noise and the delay fluctuation of the variable delay circuit in the case where a noise filter (power supply filter) is provided and the case where it is not provided will be considered.

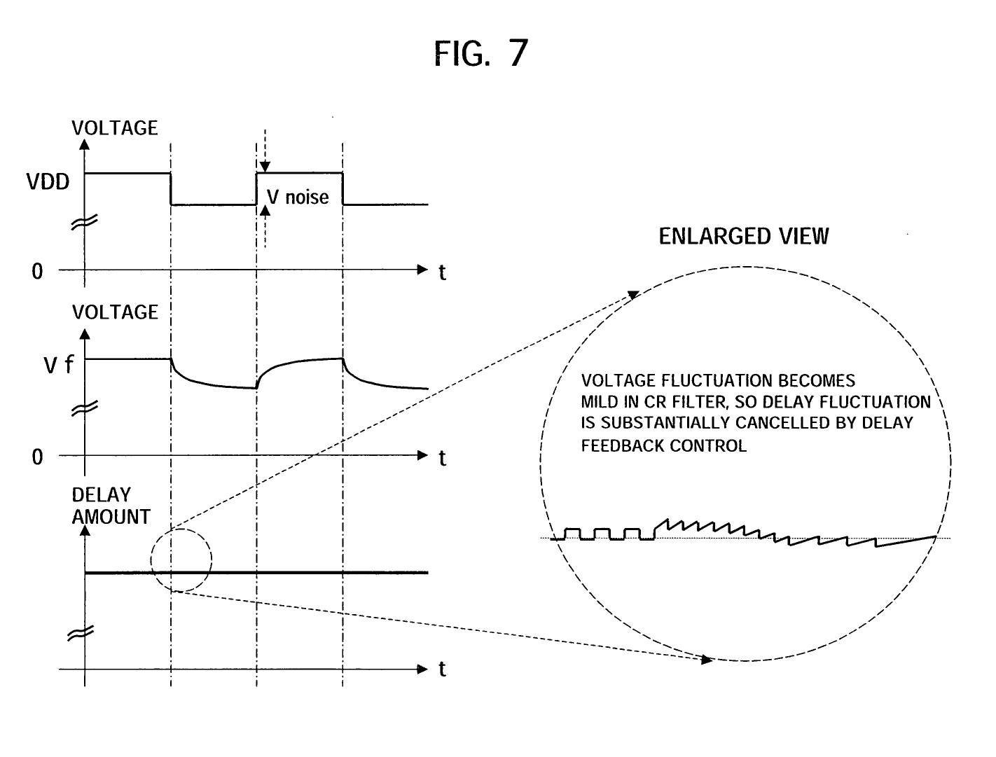

FIG. 7 is a diagram of the situation of the power supply noise and the delay fluctuation of the variable delay circuit in the case where a noise filter (power supply filter) is provided as in the present embodiment.

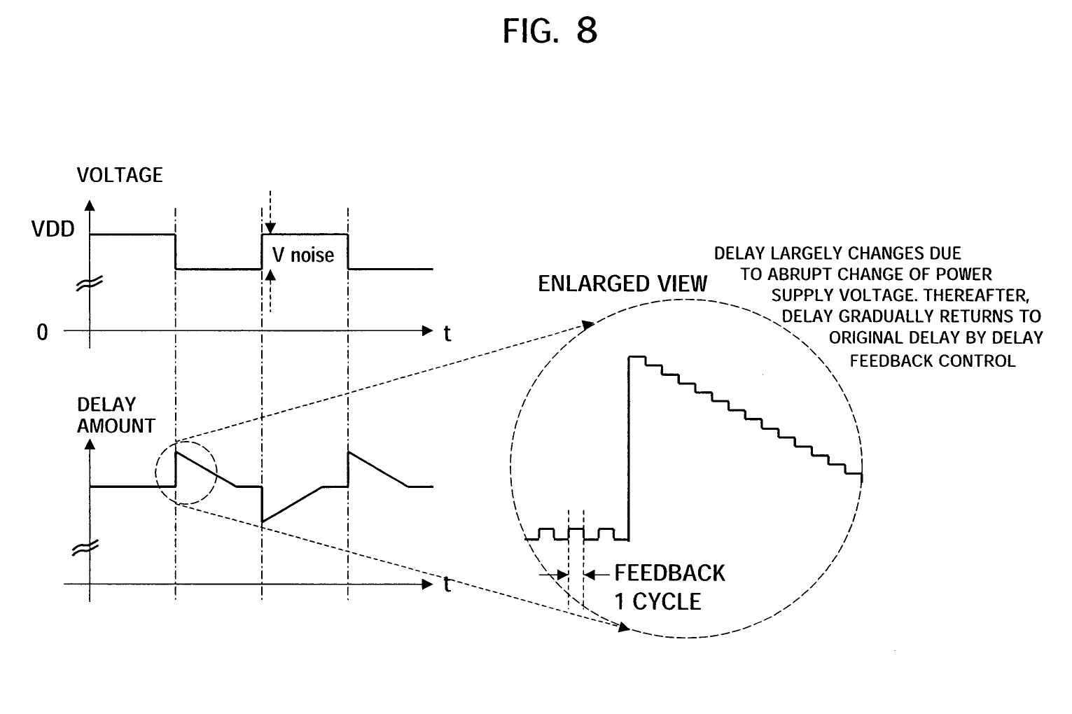

FIG. 8 is a diagram of the situation of the power supply noise and the delay fluctuation of the variable delay circuit in the case where a noise filter (power supply filter) is not provided.

As in the present embodiment, when a noise filter (power supply filter) is provided, as shown in FIG. 7, the voltage fluctuation becomes mild in the CR filter, therefore the delay fluctuation is substantially cancelled by the delay feedback control. Contrary to this, when a noise filter (power supply filter) is not provided, as shown in FIG. 8, the delay also largely changes by the abrupt change of the power supply voltage. Thereafter, the delay gradually returns to the original delay by the delay feedback control.

According to the first embodiment, a delay stabilization circuit able to suppress a drop in the stability of the delay or frequency and a cost increase and also able to shorten the design time can be provided.

Note that the noise filter constituted by the CR filter can be integrated on the same chip as the variable delay circuit 111 or the ring oscillator 11 and the delay feedback control circuit 12 or can be externally attached. Further, it is possible to form only the resistors R1 and R2 on the same chip as the variable delay circuit and externally connect the capacitors through connection pins. These and other various modifications are possible.

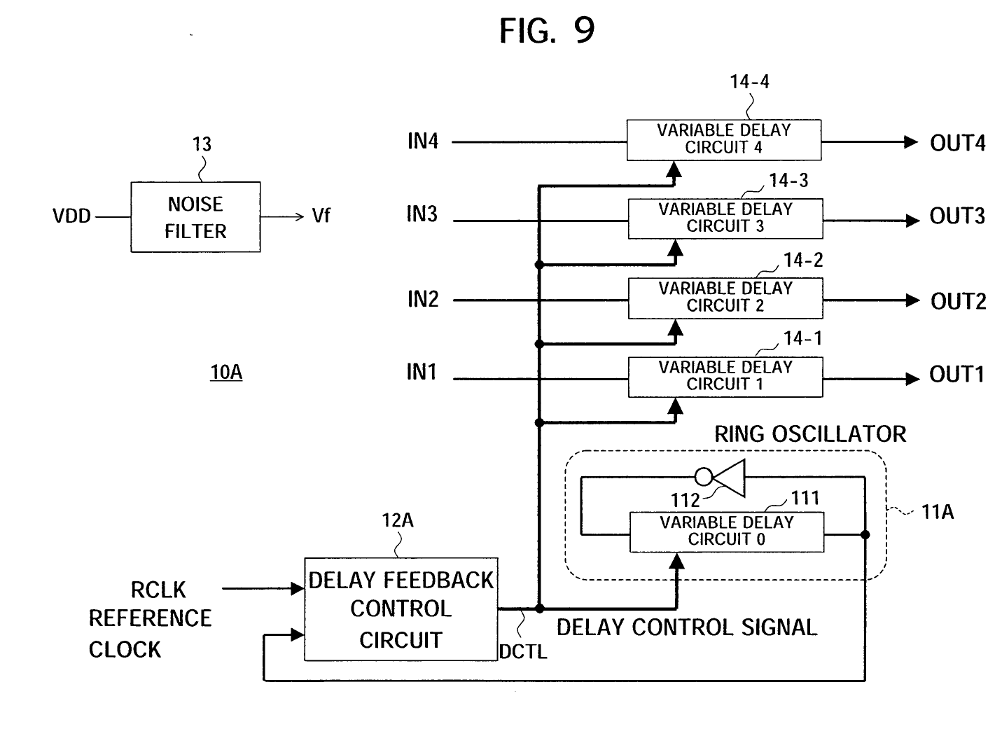

FIG. 9 is a circuit diagram of a delay stabilization 20 circuit according to a second embodiment of the present invention.

The difference of the delay stabilization circuit 10A of the second embodiment from the delay stabilization circuit 10 of the first embodiment resides in that the circuit is made a DLL used in an open loop instead of a PLL.

In the second embodiment, it is possible to use the variable delay circuit 111 of the ring oscillator 11A as the delay measurement signal generation circuit by time multiplexing, but the delay stabilization circuit 10A of the second embodiment is provided with variable delay circuits 14-1 to 14-4 separate from the variable delay circuit 111 of the ring oscillator 11A as the delay measurement signal generation circuit as shown in FIG. 9.

In the delay stabilization circuit 10A, the delay feedback control circuit 12A compares the output of the ring oscillator 11A and the reference clock RCLK to generate the delay control signal DCTL for suppressing delay fluctuation, outputs the signal to the variable delay circuit 111 of the ring oscillator 11A and, at the same time, outputs the signal to the variable delay circuits 14-1 to 14-4 delaying and outputting the input signals IN1 to IN4.

The variable delay circuits 14-1 to 14-4 can be configured in the same way as FIG. 2 and FIG. 3. The delay feedback control circuit 12A is also configured in the same way as FIG. 4.

The noise filter 13 has the same configuration as the case of the first embodiment (FIG. 5 and FIG. 6), functions as a passive power supply filter configured by a capacitor and a resistor (CR passive filter), and supplies the power supply voltage VDD from a not shown original power source passed through the passive power supply filter configured by the resistor and the capacitor, that is, the voltage Vf, as the drive power to the delay stabilization circuit 10A as a whole or the portion including the variable delay circuits 111 (ring oscillator in the configuration of FIG. 9) and 14-1 to 14-4 (ring oscillators in the configuration of FIG. 1).

In the second embodiment as well, a delay stabilization circuit able to suppress a drop in the stability of the delay or frequency and a cost increase and also able to shorten the design time can be provided.

Note that the noise filter constituted by the CR filter can be integrated on the same chip as the variable delay circuit 111 or the ring oscillator 11A and the delay feedback control circuit 12A or can be externally attached. Further, it is possible to form only the resistors R1 and R2 on the same chip as the variable delay circuits and externally connect the capacitors through connection pins. These and other various modifications are possible.

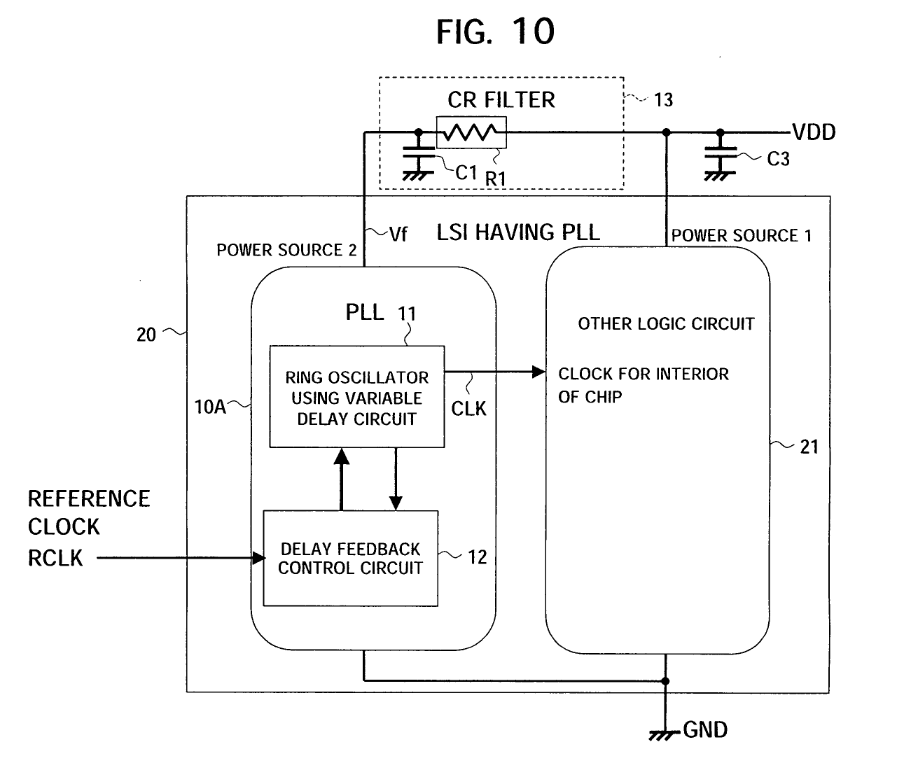

FIG. 10 is a circuit diagram of a delay stabilization circuit integrated in a semiconductor according to a third embodiment of the present invention.

The third embodiment shows an example of a case where a delay stabilization circuit 10 configured as a PLL explained in the first embodiment is mounted on an LSI 20 and there is another logic circuit 21 which becomes a large noise source on the LSI 20. Further, the output clock CLK of the delay stabilization circuit 10 constituted as a PLL is supplied to the logic circuit 21 etc. and used as an internal chip clock of the LSI 20. As the noise filter 13 in the third embodiment, a filter having a single-stage configuration shown in FIG. 5 is applied. It is arranged so as to separate in power supply the logic circuit 21 which becomes the noise source and the variable delay circuits, the entire delay stabilization circuit, or the portion of the delay stabilization circuit where the effect on delay stability is large from the other logic circuit 21 which becomes the noise source.

Namely, the voltage Vf passed through the noise filter (power supply filter) 13 is supplied to the delay stabilization circuit 10, and the power supply voltage VDD is supplied to the other logic circuit 21.

According to the third embodiment, even when the delay stabilization circuit 10 forming a PLL and another logic circuit 21 are integrated on the same LSI 20, the power supply voltage VDD directly supplied to the logic circuit 21 which becomes the noise source is filtered by the noise filter (power supply filter) 13, therefore the voltage fluctuation becomes mild in the CR filter, so the delay fluctuation is substantially cancelled by the delay feedback control. Accordingly, it is possible to realize clock generation having a high precision.

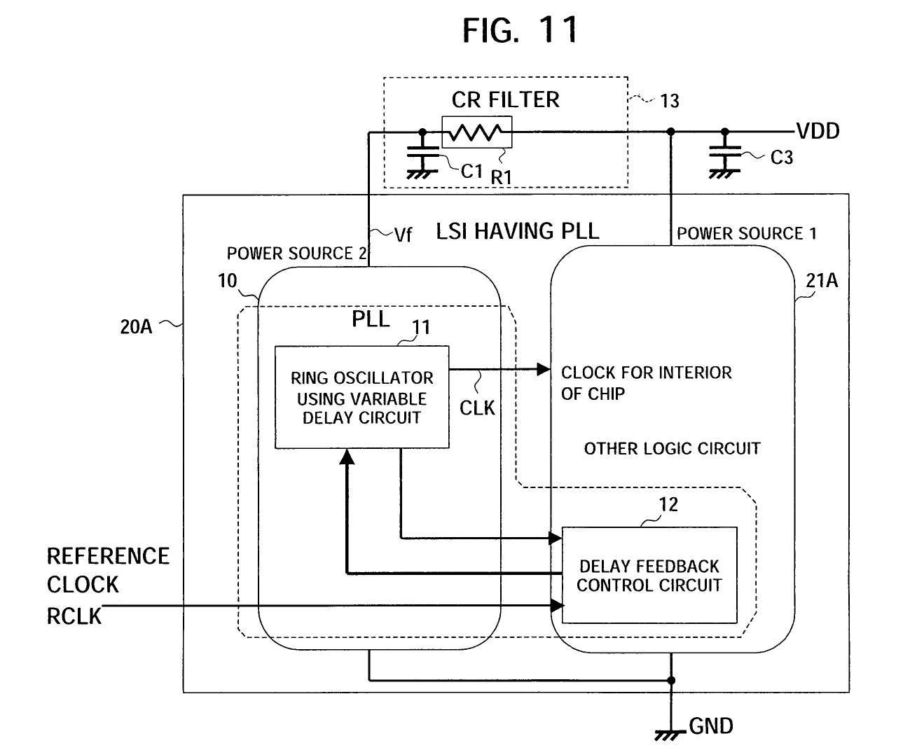

FIG. 11 is a circuit diagram of a delay stabilization circuit integrated in a semiconductor according to fourth embodiment of the present invention.

In the fourth embodiment, in a configuration of the case as explained in the third embodiment where a delay stabilization circuit 10 configured as a PLL is mounted on an LSI 20 and there is another logic circuit 21 which becomes a large noise source on the LSI 20, the delay feedback control circuit 12 of the components of the delay stabilization circuit 10 is arranged at the logic circuit 21 side to which the power supply voltage VDD is supplied.

According to the fourth embodiment, even if the delay stabilization circuit 10 configured as a PLL and the other logic circuit 21 are integrated on the same LSI 20, the power supply voltage VDD directly supplied to the logic circuit 21 which becomes the noise source is filtered by the noise filter (power supply filter) 13, therefore the voltage fluctuation becomes mild in the CR filter, so the delay fluctuation of the variable delay circuit of the ring oscillator 11 is substantially cancelled by the delay feedback control. Accordingly, it is possible to realize clock generation with a high precision.

In this way, even in a separate power supply circuit configuration where only the variable delay circuit system is supplied with the voltage Vf passed through the noise filter 13, it is possible to obtain the same effects as those of the third embodiment.

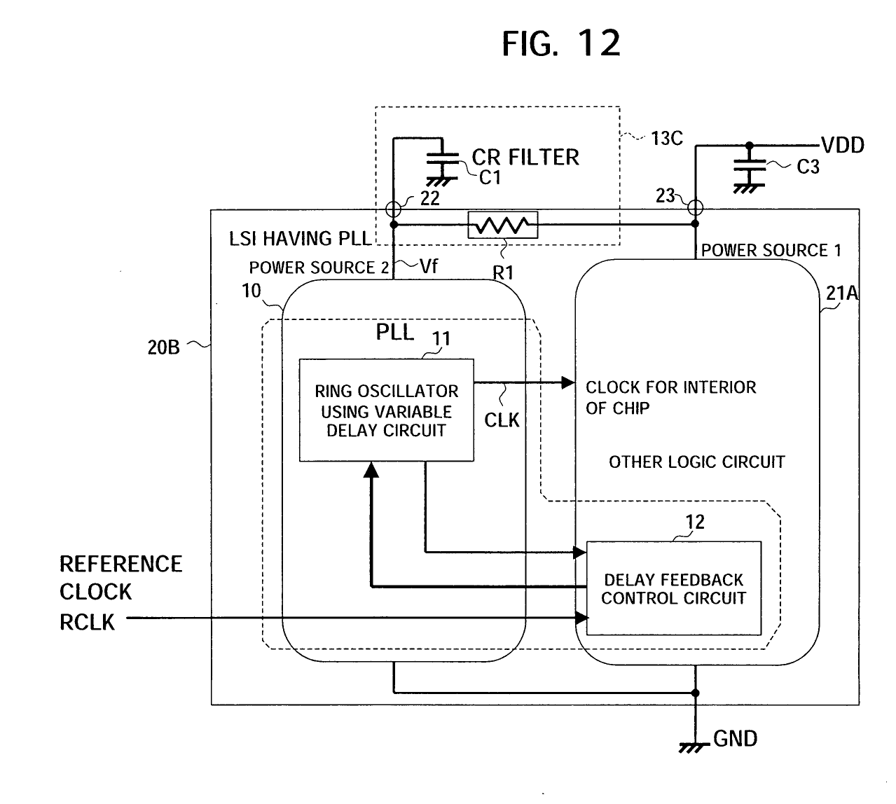

FIG. 12 is a circuit diagram of a delay stabilization circuit integrated in a semiconductor according to a fifth embodiment of the present invention.

The difference of the fifth embodiment from the fourth embodiment resides in the configuration of forming only the resistor R1 of the noise filter 13C on the same LSI 20B as the variable delay circuit and externally connecting the capacitors C1 and C3 through connection pins 22 and 23. This on-chip resistor is formed by for example an interconnect made of metal, polysilicon, or the like.

According to the fifth embodiment, even when the delay stabilization circuit 10 configured as a PLL and another logic circuit 21 are integrated on the same LSI 20B, the power supply voltage VDD directly supplied to the logic circuit 21 which becomes the noise source is filtered by the noise filter (power supply filter) 13C, therefore the voltage fluctuation becomes mild in the CR filter, so the delay fluctuation of the variable delay circuit of the ring oscillator 11 is substantially cancelled by the delay feedback control. Accordingly, it is possible to realize clock generation with a high precision.

In this way, even when adopting a separate power supply circuit configuration where the resistor of the noise filter 13C is formed as an on-chip resistor and the voltage Vf passed through the noise filter 13C is supplied to only the variable delay circuit system, it is possible to obtain the same effects as those by the third embodiment.

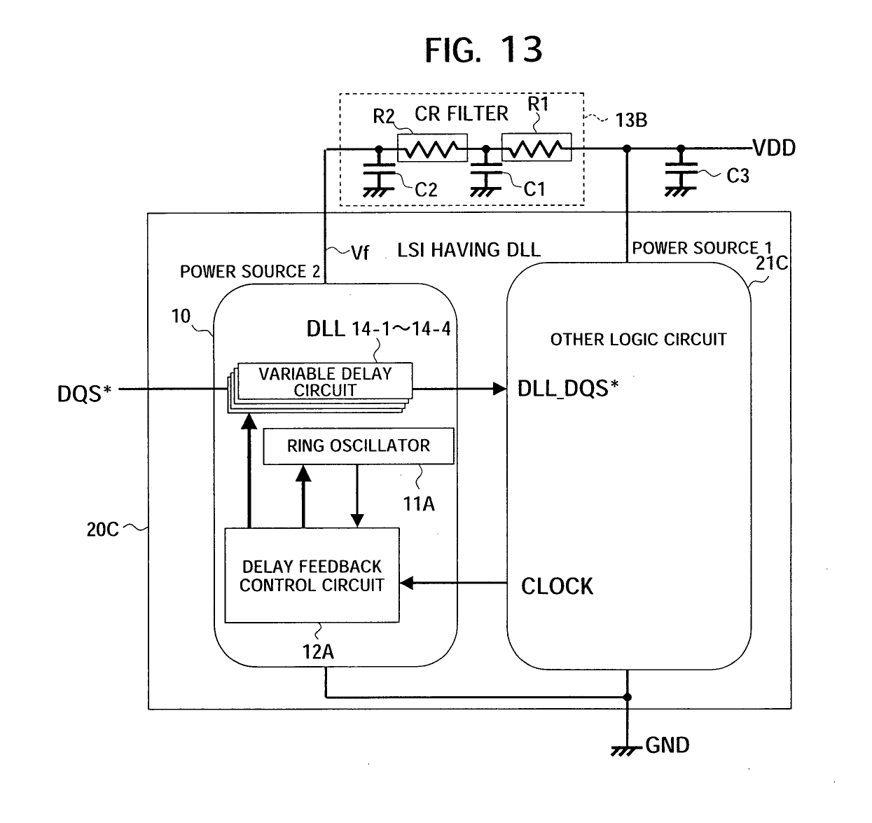

FIG. 13 is a circuit diagram of a delay stabilization 15 circuit integrated in a semiconductor according to a sixth embodiment of the present invention.

The sixth embodiment shows an example of a case where a delay stabilization circuit 10A configured as a DLL explained in the second embodiment is mounted on an LSI 20C and there is another logic circuit 21C which becomes a large noise source on the LSI 20C. Further, a signal DOS* delayed by the delay stabilization circuit 10 constituted by the DLL is supplied to the logic circuit 21C where it is subjected to predetermined processing. As the noise filter 13B in the sixth embodiment, a filter having the two-stage configuration shown in FIG. 6 is applied. It is arranged in order to separate in power supply the logic circuit 21C which becomes the noise source and the variable delay circuit, the entire delay stabilization circuit, or the portion of the delay stabilization circuit where the effect on delay stability is large from the other logic circuit 21C which becomes the noise source.

Namely, the voltage Vf passed through the noise filter (power supply filter) 13 is supplied to the delay stabilization circuit 10A, and the power supply voltage VDD is supplied to the other logic circuit 21C.

According to the sixth embodiment, even when the delay stabilization circuit 10A configured as a DLL and the other logic circuit 21C are integrated on the same LSI 20C, the power supply voltage VDD directly supplied to the logic circuit 21C which becomes the noise source is filtered by the noise filter (power supply filter) 13B, therefore the voltage fluctuation becomes mild in the CR filter, so the delay fluctuation is substantially cancelled by the delay feedback control. Accordingly, it is possible to realize clock generation with a high precision.

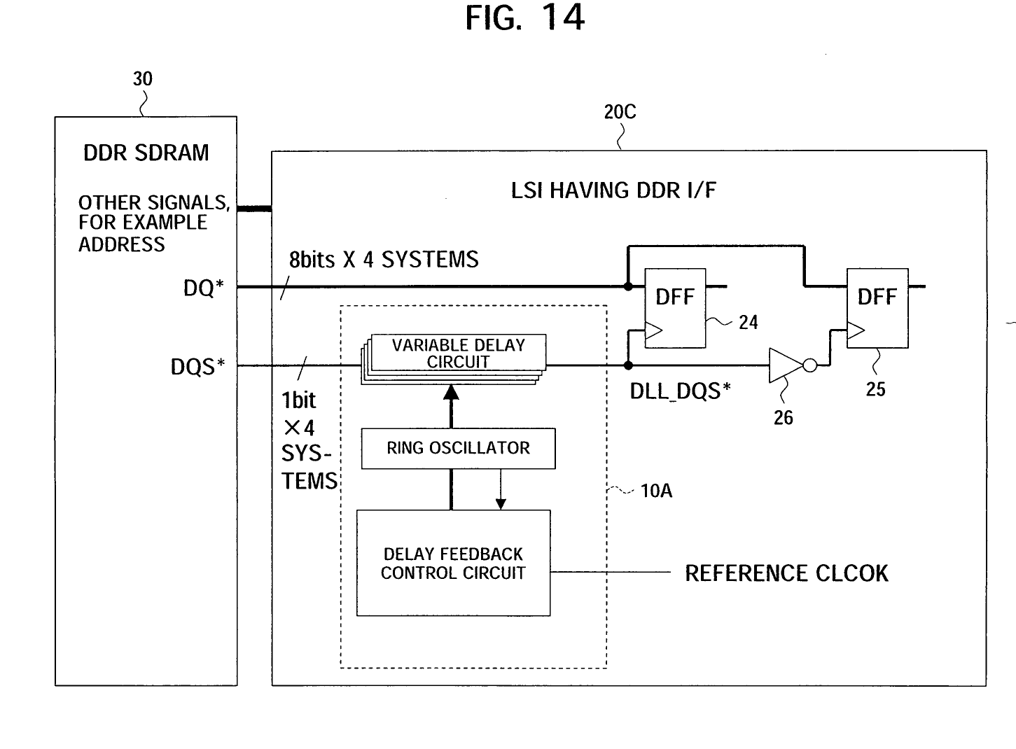

The delay stabilization circuit 10A configured as a DLL having such a characteristic can be used as an interface circuit of for example a DDR DRAM as shown in FIG. 14. In FIG. 14, 30 indicates a DDR synchronization type DRAM, and 20C indicates the LSI according to the sixth embodiment. Further, 24 and 25 indicate D-type flip-flops, and 26 indicates an inverter. In FIG. 14, a power supply system is omitted.

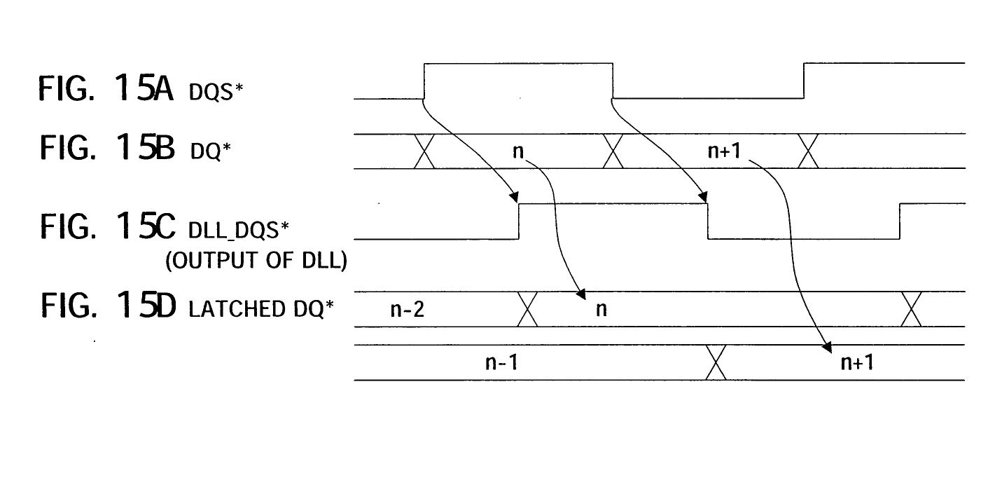

FIGS. 15A to 15D are timing charts for explaining the operation of the DLL functioning as the DDR interface.

When data is read out from the DDR DRAM 30, a signal DQS* showing a timing of change of read data is output for each certain group (for example for each 8 bits) of read data DQ*. In order to latch this read data inside the LSI 20C, it is necessary to delay the signal DQS* by exactly about ¼ of the clock cycle and use the same as an acquisition clock. The delay stabilization circuit 10A configured as a DLL generates a stable delayed signal DQS for this purpose.

In this way, this can be applied as the DDR interface and can generate a stable clock signal with little delay fluctuation.

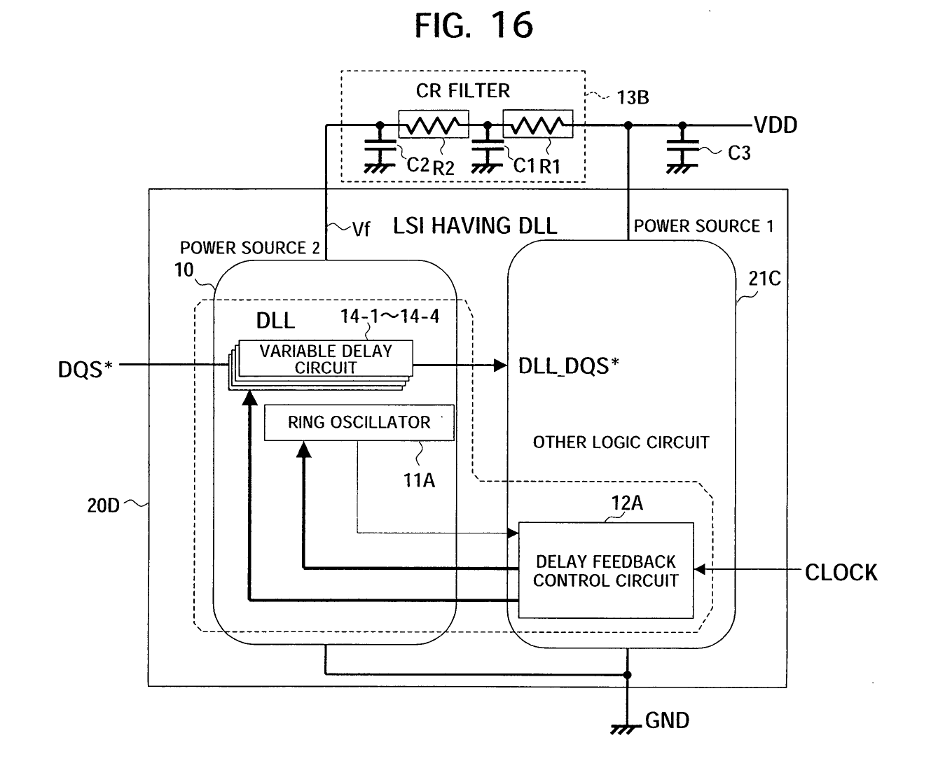

FIG. 16 is a circuit diagram of a delay stabilization circuit integrated in a semiconductor according to a seventh embodiment of the present invention.

In the seventh embodiment, in the configuration of the case explained in the sixth embodiment where a delay stabilization circuit 10A configured as a DLL is mounted on an LSI 20C and there is another logic circuit 21C which becomes a large noise source on the LSI 20C, the delay feedback control circuit 12 of the components of the delay stabilization circuit 10A is arranged at the logic circuit 21C side to which the power supply voltage VDD is supplied.

According to the seventh embodiment, even when the delay stabilization circuit 10A configured as a DLL and the other logic circuit 21C are integrated on the same LSI 20C, the power supply voltage VDD directly supplied to the logic circuit 21C which becomes the noise source is filtered by the noise filter (power supply filter) 13B, therefore the voltage fluctuation becomes mild in the CR filter, so the delay fluctuation of the variable delay circuit of the ring oscillator 11A is substantially cancelled by the delay feedback control. Accordingly, it is possible to realize clock generation with a high precision.

In this way, even with a separate power supply circuit configuration where only the variable delay circuit system is supplied the voltage Vf passed through the noise filter 13B, it is possible to obtain the same effects as those by the sixth embodiment.

According to embodiments explained above, the following effects can be obtained.

Namely, the delay stabilization circuit is configured 25 by only logic gates, therefore the design is easy in comparison with the analog system. Further, along with the new generations of the LSI production process, the area can be reduced and the power consumption can be reduced by the same ratio as that of the logic circuit. The original power source can be shared with the other principal logic circuits of the LSI, a dedicated active stabilization power source is unnecessary, and a delay stability which is sufficient in practical use can be obtained by only a power supply filter configured by a cheap resistor and capacitor. The combination of a digital system delay stabilization circuit and a CR power supply filter, which was not selected due to the past belief of the adverse effect of the drop in the power supply voltage due to the resistance, has merits increasing over the past art and less demerits due to the following measures, the new generations of processing technology, and a rising trend of the clock frequency used in LSI's.

By separating the power supply of only the required portion, the power supply current to be stabilized can be kept small. As a result, the voltage drop due to the resistor used in the filter becomes small.

When the permissible value of the voltage drop and the time constant (CxR) of the filter are the same, the resistance value can be made higher by the amount of reduction of the current due to the power supply separation, and the capacitor may be smaller by that amount.

In general, the power supply voltage for the logic gates has becomes lower along with the new generations of processing technology, therefore the new generations enable use to be made of a capacitor having a lower durability and also reduce the power supply current, therefore smaller sized capacitors can be used.

The later the generation of processing technology, the more the operation frequency of the internal circuit can be raised, the shorter the DDR access cycle in an actual chip, and the smaller the delay formed by the DLL.

The oscillation frequency becomes high also in a PLL, and the delay amount of the variable delay circuit in the PLL tends to become smaller.

According to that, in the digital system, the cycle of the delay feedback control becomes smaller, the time constant of the power supply filter can be made smaller in accordance with this, and it becomes possible to use a further small sized capacitor.

Accordingly, the power supply filter can be mounted by smaller sized chip parts cheaply and with smaller area.

Further, a multi-chip module and multi-chip package mounting a variety of chips and parts on one package and further the mounting of a power supply filter onto a chip do not use any inductors, therefore the operation is easy, the cost is low, and the possibility for obtaining cost merit in comparison with the past art will rise in the future.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A delay stabilization circuit comprising:
a passive noise filter configured by a capacitor and a resistor, a variable delay circuit including a logic gate to which power of a power source is supplied through the noise filter, and
a feedback control circuit for suppressing delay fluctuation of the variable delay circuit using a clock input from outside as a reference.

2. A delay stabilization circuit as set forth in claim 1, wherein:
the delay stabilization circuit has a pin for connecting only a capacitor forming the noise filter, the resistor forming the noise filter is mounted on an integrated circuit in a same manner as the variable delay circuit, the capacitor forming the noise filter is arranged on the outside of the chip, and the capacitor forming the noise filter is connected to the pin.

3. A delay stabilization circuit as set forth in claim 1, wherein the resistor and the capacitor forming the noise filter are mounted on the integrated circuit with the variable delay circuit.

4. A delay stabilization circuit as set forth in claim 1, wherein at least the variable delay circuit is separated in power supply from other circuits mounted on the same integrated circuit, and power from the power source is supplied by the noise filter.

5. A delay stabilization circuit as set forth in claim 1, wherein a time constant of the noise filter is set larger than a cycle of the delay feedback control.

6. A delay stabilization circuit comprising:
a passive noise filter configured by a capacitor and a resistor,
a ring oscillator including a variable delay circuit including a logic gate to which a power of a power source is supplied through the noise filter; and
a feedback control circuit outputting a delay control signal for suppressing delay fluctuation of the variable delay circuit using a clock input from outside as a reference to the variable delay circuit, wherein the clock is output by the ring oscillator.

7. A delay stabilization circuit comprising:
a passive noise filter configured by a capacitor and a resistor,
a ring oscillator including a variable delay circuit including a logic gate to which a power of a power source is supplied through the noise filter,
at least one output use delay variable circuit supplied with power of the power source through the noise filter and delaying the input signal with a delay amount in accordance with the delay control signal, and
a feedback control circuit outputting a delay control signal for suppressing delay fluctuation of the variable delay circuit using a clock input from outside as a reference to the variable delay circuit of the ring oscillator and the output use variable delay circuit.

8. A delay stabilization circuit as set forth in claim 6, wherein a time constant of the noise filter is set larger than a cycle of the delay feedback control.

9. A delay stabilization circuit as set forth in claim 7, wherein a time constant of the noise filter is set larger than a cycle of the delay feedback control.

10. A semiconductor integrated circuit comprising:
a passive noise filter configured by a capacitor and a resistor,
a ring oscillator including a variable delay circuit having a logic gate and outputting a clock,
a feedback control circuit outputting a delay control signal for suppressing delay fluctuation of the variable delay circuit using a clock input from the outside as a reference to the variable delay circuit, and a logic circuit using an output clock of the ring oscillator as an operation clock, wherein
at least the ring oscillator, feedback control circuit, and logic circuit are mounted on the same integrated circuit,
power from a power source is supplied to at least the logic circuit, and
power of the power source passed through the noise filter is supplied to at least the variable delay circuit of the ring oscillator.

11. A semiconductor integrated circuit comprising:
a passive noise filter configured by a capacitor and a resistor,
a ring oscillator including a variable delay circuit having a logic gate,
at least one output use delay variable circuit supplied with power of a power source through the noise filter and delaying an input signal with a delay amount in accordance with a delay control signal,
a feedback control circuit outputting a delay control signal for suppressing delay fluctuation of the variable delay circuit using a clock input from outside as a reference to the variable delay circuit of the ring oscillator and the output use variable delay circuit, and
a logic circuit for receiving the output signal of the output use variable delay circuit and performing predetermined processing, wherein
at least the output use variable delay circuit, ring oscillator, feedback control circuit, and logic circuit are mounted on the same integrated circuit,
power from the power source is supplied to at least the logic circuit, and power of the power source passed through the noise filter is supplied to at least the output use variable delay circuit and the variable delay circuit of the ring oscillator among the output use variable delay circuit, the variable delay circuit, and feedback control circuit.

12. A semiconductor integrated circuit as set forth in claim 10, wherein a time constant of the noise filter is set larger than a cycle of the delay feedback control.

13. A semiconductor integrated circuit as set forth in claim 11, wherein a time constant of the noise filter is set larger than a cycle of the delay feedback control.
